(19) United States
(12) Patent Application Publication
(10) Pub. No.: US 2022/0109433 A1
(43) Pub. Date: Apr. 7, 2022

(54) PEAK SELF-NORMALIZATION GAIN CONTROL BASED ON HOPF RESONATORS CASCADE SIGNAL SPECTRAL DECOMPOSITION

(71) Applicant: Daniel David Ben-Dayan Rubin, Jerusalem (IL)

(72) Inventor: Daniel David Ben-Dayan Rubin, Jerusalem (IL)

(21) Appl. No.: 17/643,652

(22) Filed: Dec. 10, 2021

(51) Int. Cl. H03H 17/02

(52) U.S. Cl. CPC H03H 17/0219; G10L 25/24

(57) ABSTRACT

This disclosure describes systems, methods, and devices related to non-linear spectral decomposition with peak self-normalization. A system may comprise a filter bank composed of a plurality of resonators cascaded in series. The system may comprise a controller to drive the filter bank, that may inject a first signal into a first resonator of the plurality of resonators. The controller may utilize a first characteristic frequency of the first resonator to drive the first resonator using the first signal. The controller may generate a first output signal of the first resonator. The controller may utilize the first output signal of the first resonator as a second input signal into a second resonator using a second characteristic frequency. The controller may continue to inject a preceding resonator output as input into a subsequent resonator of the plurality of resonators in series in order to get spectral decomposition with peak normalized characteristics.

### TECHNICAL FIELD

This disclosure generally relates to systems and methods for spectral decomposition and, more particularly, to peak self-normalization gain control based on Hopf resonators cascade signal spectral decomposition.

### BACKGROUND

Sound recognition is a technique that uses pattern recognition as well as audio signal analysis methodologies. Preliminary data processing, feature extraction, and classification techniques are all present in sound recognition technology.

### BRIEF DESCRIPTION OF THE DRAWINGS

FIG. 1 illustrates an example environment of a peak self-normalization system, in accordance with one or more example embodiments of the present disclosure.

FIG. 2A depicts a single Hopf resonator response to a single tone/amplitude persistent input, in accordance with one or more example embodiments of the present disclosure.

FIG. 2B depicts a filter bank composed of a plurality of Hopf resonators, in accordance with one or more example embodiments of the present disclosure.

FIGS. 3A-3B depict illustrative schematic diagrams for peak self-normalization, in accordance with one or more example embodiments of the present disclosure.

FIGS. 4A-4B depict illustrative schematic diagrams for peak self-normalization, in accordance with one or more example embodiments of the present disclosure.

FIG. 5 depicts an illustrative schematic diagram for peak self-normalization, in accordance with one or more example embodiments of the present disclosure.

FIG. 6 illustrates a flow diagram of a process for an illustrative peak self-normalization system, in accordance with one or more example embodiments of the present disclosure.

FIG. 7 is a block diagram illustrating an example of a computing device or computing system upon which any of one or more techniques (e.g., methods) may be performed, in accordance with one or more example embodiments of the present disclosure.

Certain implementations will now be described more fully below with reference to the accompanying drawings, in which various implementations and/or aspects are shown. However, various aspects may be implemented in many different forms and should not be construed as limited to the implementations set forth herein; rather, these implementations are provided so that this disclosure will be thorough and complete, and will fully convey the scope of the disclosure to those skilled in the art. Like numbers in the figures refer to like elements throughout. Hence, if a feature is used across several drawings, the number used to identify the feature in the drawing where the feature first appeared will be used in later drawings.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

Hearing device design and sound signal processing can both benefit from ear modeling. A family of nonlinear differential equations (partial differential equations (PDEs)) is formed by ear models based on mechanics and neural phenomenology of the inner ear (e.g., cochlea). In agreement with actual evidence, these PDEs reflect the main nonlinear processes in hearing, such as combination frequency production, compression, and suppression. The PDEs aid in the generation of linear and nonlinear auditory transforms, as well as a class of orthogonal discrete auditory, transforms with a larger spectrum than the discrete Fourier transform, which is more in accordance with human hearing. Some examples that may benefit from this type of modeling include key phrase detection (KPD), which includes systems that recognize certain key phrases from a user speaking into a microphone on the device that may be used by automatic speech recognition (ASR) devices. Other benefits may include speaker detection, faint sound detection, or other types of detections. There is a need to enhance the spectral decomposition of a sound toward peak normalization.

While pre-processing a signal for spectral decomposition using a bank of non-linear Hopf resonators with a number of resonators per octave, peak normalization may be achieved. The number of resonators may be a number that is more than 5 resonators per octave and the incoming signal amplitude may be between −80 dB to 120 dB (human (sub) detectability). An example resonator may be a Hopf resonator. The Hopf resonator can be efficiently implemented by numerically integrating a non-linear differential equation. The bank of resonators (filters) serves as a direct audio signal pre-processing stage for spectral decomposition and peak normalization.

Currently, there are no known previous spectral decomposition methods which results are intrinsically peak normalized as the present approach in accordance with one or more example embodiments of the present disclosure. Lacking alternative methods of spectral decomposition, for instance, the mel-frequency cepstral coefficients (MFCC), are often coupled with values normalization prior to the spectral decomposition.

Example embodiments of the present disclosure relate to systems, methods, and devices for peak self-normalization gain control based on Hopf resonators cascade signal spectral decomposition.

In one or more embodiments, a peak self-normalization system may include a filter bank that is composed of Hopf resonators, each returning a temporal signal that maximally resonates at its characteristic frequency. The characteristic frequencies of the filter bank are arranged from high to low pitch while the number of resonators per octave defines the density of the bank. Hopf resonators have the property of amplifying weak signals and compressing loud ones. When cascaded in a bank above a given density, an emerging phenomenon of signal peak normalization for both loud and weak signals alike may be observed.

By cascading nonlinear resonators, a peak self-normalization system may mimic an auditory stream. By encoding/decoding for any application, a peak self-normalization system may facilitate similarity to human sound reception or other types of sounds. That is, the cascaded filter bank may expand beyond speech recognition to other sound recognitions, such as engine/motor sounds for anomaly recognition. Sounds that have a larger bandwidth (several 100s of kHz), which could go beyond what is audible could be recorded with a specialized microphone. The spectral decomposition based on these recorded sounds may be achieved using the cascaded filter bank.

Peak self-normalization effect may be obtained using a configuration of a cascaded filter bank that is characterized by increasing the density per octave. In the context of designing compact spectral decomposition modules that would become an alternative for short-time Fourier transform (STFT) and/or MFCC in the future of the artificial intelligence (AI) systems for various audio applications and more generally spectral decomposition, a more compact approach compared to existing ones both in terms of computing and of memory footprint is proposed.

In one or more embodiments, a peak self-normalization system may facilitate varying the density of cascaded Hopf resonators in a filter bank in order to get spectral decomposition with peak normalized characteristics.

In one or more embodiments, a peak self-normalization system may facilitate sweeping frequencies from high to low and determining the responses of the cascade of Hopf resonators. A peak self-normalization system may group different envelops at the same section/octave density to obtain the peak normalization curves.

In one or more embodiments, the high frequency earliest sections (resonators) in a cascaded filter bank of Hopf resonators arranged in series, are responsible for amplifying (or compressing) the weak (or loud) signal. Increasing the density of sections/octave the normalization is tighter, for example, any amplitude is fully peak normalized across several orders of dynamic range −80db-120db and sharper, that is, letting early HF sections already encoding for peak normalized inputs processed by earlier HF resonators in the bank. This peak self-normalization gain control is a novel observation, an emergent property of cascading Hopf nonlinearities at larger densities.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

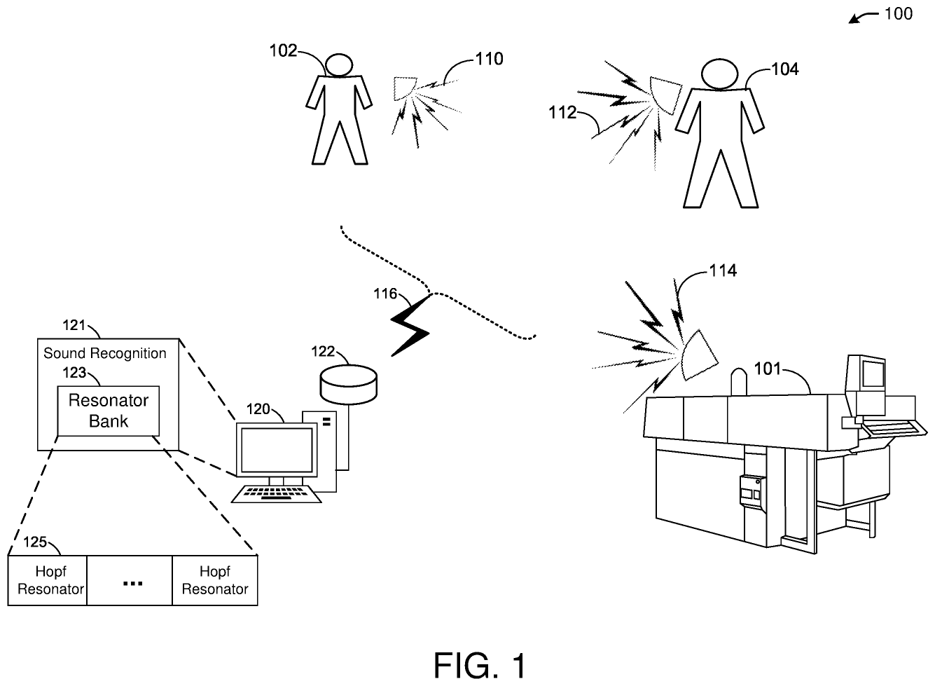

FIG. 1 depicts an illustrative schematic diagram for peak self-normalization, in accordance with one or more example embodiments of the present disclosure.

Recent advances in speech detection, recognition, analysis, generation, etc., very often rely on spectral decomposition preprocessing that is commonly carried out by either short-time Fourier transform (STFT) or Mel-frequency cepstrum coefficients (MFCC). For instance, the MFCC is a transformation that is often considered for tasks that do not require signal (re-)generation such as detection/classification. MFCC values are not very robust in the presence of additive noise, and so it is common to normalize their values in speech recognition systems to lessen the influence of noise.

Referring to FIG. 1, there is shown an example that includes a machine 101 operating in an environment. The machine 101 may generate sound 114 during operation. In addition to the machine 101, users 102 and 104 may be communicating and generating speech 110 and speech 112. The various sounds (e.g., sound 114, speech 110, and speech 112) may overlap and interlace with each other. It should be understood that although the machine shown in FIG. 1 is a machine, this is not a limitation and other types of noise sources may be present in the peak self-normalization system.

In one or more embodiments, the peak self-normalization system may facilitate using sensors such as a microphone to detect sounds in a vicinity of a machine without the need to be attached to the machine.

In one or more embodiments, the peak self-normalization system may utilize a computer system 120 that comprises a sensor 122 (e.g., a microphone) that may be capable of detecting the various sounds. The sound 116 may be a combination of the various sounds when received by the sensor 122.

In one or more embodiments, the peak self-normalization system may capture sound 116 using the sensor 122. The computer system 120 may perform sound recognition 121. Sound recognition 121 may employ a resonator (filter) bank 123 that is composed of cascaded Hopf resonators 125. Sound recognition 121 may be used to identify a speaker, to separate different sources, to isolate specific spoken words, to accurately process loud and faint sounds, and other functions.

In one or more embodiments, the peak self-normalization system may facilitate utilizing artificial intelligence (AI) or machine learning to isolate portions of captured sounds (e.g., sound 114, speech 110, and speech 112) to determine whether human speech (e.g., speech 110 and speech 112) is present or overlaps the sound 114 coming from the machine 101 itself.

In one or more embodiments, a peak self-normalization system may vary the density of cascaded Hopf resonators 125 in the resonator (filter) bank 123, which accurately extracts the spectral components of the incoming signal (e.g., sound 116), in order to obtain peak self-normalization. Achieving a peak self-normalization may enhance sound recognition 121. Hopf dynamics has wide-ranging signal processing applications. A prominent role of resonators of such nature is as active elements in models of the auditory pathway (up to the auditory nerve cells), which provides a class of biologically inspired methods of audio pre-processing. Moreover, various audio applications in the artificial intelligence (AI) domain have recently involved neuromorphic computing as a very promising means for extremely low power and efficient computing.

In one or more embodiments, utilizing a dedicated asynchronous event-based processor (where the events are defined as (graded) spikes among the minimal computational blocks—the neurons), a peak self-normalization system may efficiently implement complex neuron dynamics integrating various differential equations including Hopf's. The peak self-normalization system, based on Hopf resonators (e.g., the cascaded Hopf resonators 125 in the resonator (filter) bank 123), may be particularly convenient because of its simplicity, compactness, and the many emerging properties it highlights.

In one or more embodiments, the peak self-normalization becomes predominant at mid-high frequency. The effect is noticeable for all input amplitudes spanning several orders of magnitude (−80 dB to −120 dB) at about 5 resonators per octave or above which is believed to be the upper limit of a healthy human hearing system. This finding contrasts earlier assumptions on the cascaded Hopf resonators 125 behavior at higher densities that mostly focused on the single resonator non-linearity contribution. This is the first time this effect of peak self-normalization is being reported.

It is understood that the above descriptions are for purposes of illustration and are not meant to be limiting.

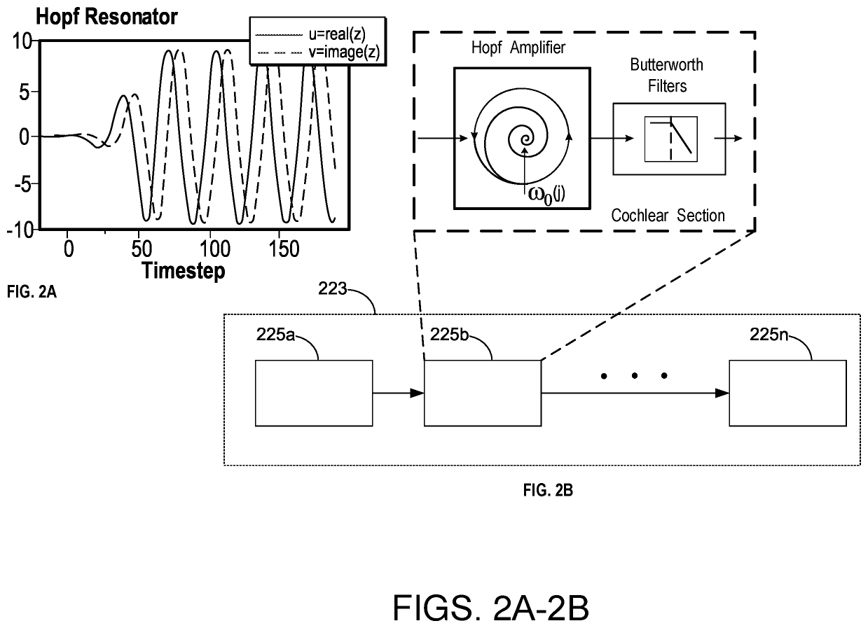

FIGS. 2A-2B depict illustrative schematic diagrams for peak self-normalization, in accordance with one or more example embodiments of the present disclosure.

Referring to FIG. 2A, there is shown an example of a single Hopf resonator response to a single tone/amplitude persistent input. The response is shown as imaginary (v) or real (u) over a time period using the single tone/amplitude as input to a Hopf resonator.

Referring to FIG. 2B, there is shown a filter bank 223 that is composed of a plurality of Hopf resonators that are cascaded together in series, where the output of a first Hopf resonator 225a is an input into the next Hopf resonator 225b and so on up to the Hopf resonator n, where n is a positive integer. Each of the Hopf resonators is referred to as a cochlear section. Cochlear modeling indicates that the basal membrane in the cochlea oscillates, selectively amplifying audio frequency (ordered from base to apex (high-frequency (HF) to a low-frequency (LF)) components. In cochlea models, membrane sections for different frequencies are modeled by a filter bank 223 that is composed of a cascade of Hopf resonators 225. Specifically, each membrane section provides a band-pass filtered version of its input to the following lower frequency section, and so on.

In one or more embodiments, a cochlea section (e.g., Hopf resonators 225) is modeled using the continuous formulation:

F(x, z)=ż=ω₀·((μ+i−|z|²)·z+x), (1)

Where z∈ [symbol] is the resonator response, and ω₀, μ∈ [symbol] are, respectively, the characteristic frequency of the cochlear section (e.g., each of the Hopf resonators 225) and the resonant sensitivity (at which the system diverges), while x∈ [symbol] is the external input to the Hopf resonator. The choice of ω₀ to scale the differential equation is more stable over the human tuning response characteristics and more conveniently requires normalized units of x and μ. Each cochlear section is modeled by combining a Hopf amplifier with a 6-th order Butterworth lowpass filter with a cutoff at 1.05ω₀. Each cochlear section model is shown with parameters μ, ω₀^{(j)} with ω₀^{(j)}>ω₀^{(j+1)} moving from a high-frequency (HF) to a low-frequency (LF) along the cochlea in the model. By driving the filter bank 223 with persistent tones, results in the emitted outputs for each resonator similar to what is shown in FIG. 2A.

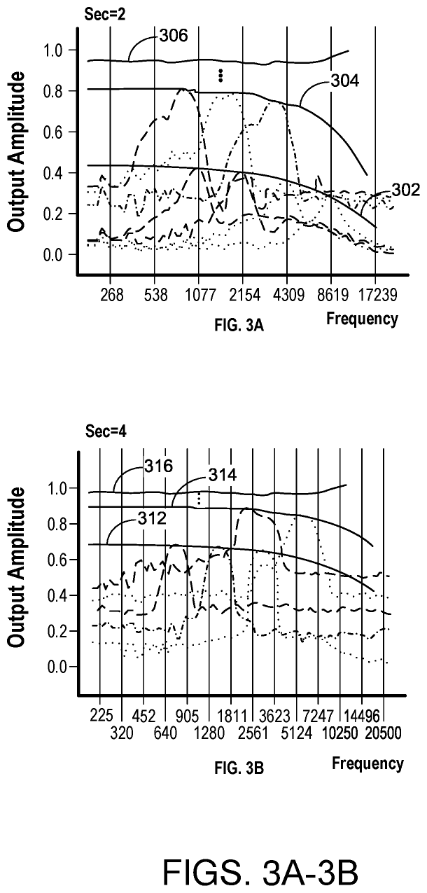

FIGS. 3A-3B depict illustrative schematic diagrams for peak self-normalization, in accordance with one or more example embodiments of the present disclosure.

In one or more embodiments, the peak of each resonator output is recorded, and for each resonator, a tuning curve or receptive field which tells its sensitivity (its maximum amplitude) for that input frequency is obtained as shown in FIGS. 3A-3B.

By integrating input on each Hopf resonator, the exponentially decaying sliding window (that characterizes the STFT kernel) naturally arises without needing to store a history of input samples. A bank of Hopf resonators at different frequencies (log scaled in the current implementation) can then be used to estimate the STFT.

The numerical integration of the Hopf resonator differential equation requires some additional precision and tolerance which the 4^{th} order Runge-Kutta (RK4) method provides. Each iteration consists of evaluating 4 times the differential equation at points (xₜ,zₜ) and its incremental adjustments via each consecutive RK4 coefficient. Since equation (1) above is complex, each function evaluation needs to be accounted for twice when translated into floating-point arithmetic. The coefficients evaluation follows the RK4 recurrence formulation (here below for convenience):

$${k}_{1} = F ( {x}_{t} , {z}_{t} ) d t , {k}_{2} = F ( {x}_{t} , {z}_{t} + \frac{{k}_{1}}{2} ) d t , {k}_{3} = F ( {x}_{t} , {z}_{t} + \frac{{k}_{2}}{2} ) d t , {k}_{4} = F ( {x}_{t} , {z}_{t} + {k}_{3} ) d t ,$$

and finally

$$k = \frac{( {k}_{1} + 2 {k}_{2} + 2 {k}_{3} + {k}_{4} )}{6} ; {z}_{t + 1} = {z}_{t} + k .$$

In the first approximation evaluating a single step in the dynamics corresponds to 5 products and 3 sums per evaluation.

Therefore, for 4 coefficients to evaluate, 20 products and 12 sums (+6 updates of the 2D point to evaluate the function at) are obtained, overall, 40 multiply-accumulate (MAC) in floating-point arithmetic are obtained. This implementation does not require buffering of the full-frame (window) to evaluate but evaluates the input sample by sample.

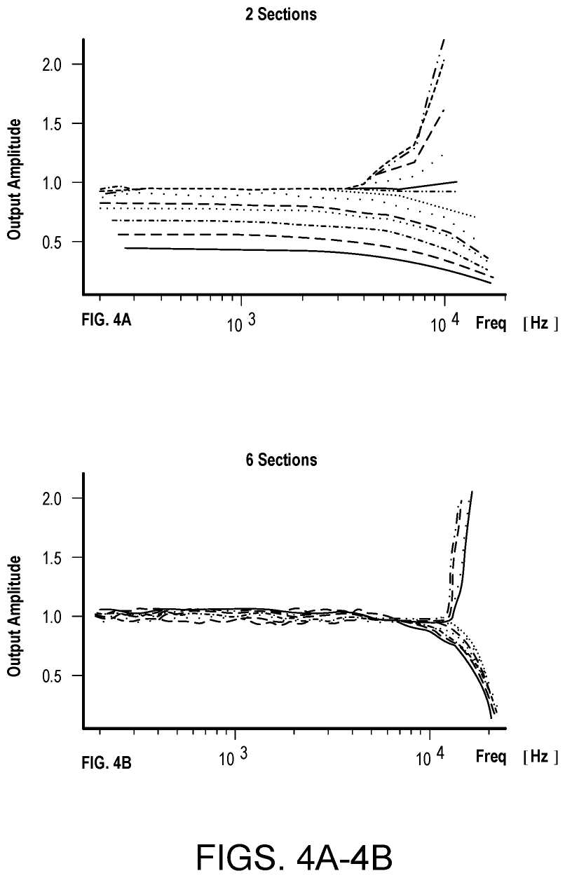

When looking at the cascaded tuning curves of all resonators for a specific run at a constant input amplitude, the peak amplitude of the receptive fields is considered for obtaining respective envelops (e.g., envelops 302, 304, and 306). If different amplitude envelops are grouped at the same sections/octave density, the peak normalization curves of FIG. 4A may be obtained. The HF earliest sections in the cascaded resonators are responsible for amplifying (or compressing) the weak (or loud) signal and as the density of section/octave increases, the normalization is tighter, for example, any amplitude is fully peak normalized across several orders of dynamic range −80 db-120 db and sharper, for example, letting early HF sections already encoding for peak normalized inputs processed by earlier HF resonators in the bank. This peak self-normalization gain control is a novel observation, an emergent property of cascading Hopf nonlinearities at larger densities.

Referring to FIGS. 3A and 3B, there are shown peak responses of pure tones for each section (e.g., a resonator in the bank of resonators) for density with 2 sections/octave (FIG. 3A) and 4 sections/octave (FIG. 3B). As can be seen, there are sets of curves with peak response for amplitudes 0.01, 0.1, 1, where the peak responses define the various envelopes (e.g., envelops 302, 304, and 306 of FIG. 3A and envelops 312, 314, and 316 of FIG. 3B). The noise in the response is due to the finite resolution of integration time used. Smoother results are observed as the integration time step is decreased. Each peak response is then interpolated with a line that corresponds to the peak envelope of all receptive fields for the considered amplitude. It can be seen that in FIG. 3B, the envelopes are closer to each other and more compacted compared to FIG. 3A based on the increasing number of sections (resonators). It should be understood that although 4 sections per octave are shown, a larger number of sections may also be used. For example, the number of sections per octave may be 5 or 6 sections.

It is understood that the above descriptions are for purposes of illustration and are not meant to be limiting.

FIGS. 4A-4B depict illustrative schematic diagrams for peak self-normalization, in accordance with one or more example embodiments of the present disclosure.

Referring to FIG. 4A, there is shown a peak normalization as a function of the input tone for various amplitudes ranging between 0.01-4.00. The curves for different amplitudes represent envelops of the peak cochlear receptive field response of each section. Here, 2 sections (FIG. 4A) versus 6 sections (FIG. 4B) per octave are shown to highlight the effect obtained while sweeping the density of sections per octave.

In one or more embodiments, mid-Frequency (midF) to LF resonators in the resonator bank receive a progressively more filtered version of the original tones, that is, the lower the resonating frequency of the resonator at hand the more cochlear filtration sections it needed to go through. The non-linear effects accumulated (e.g., sub-harmonics, which are also explained by the processing of the envelope of the complex resonator state) at midF to LF resonators make their response unique and with a distinct signature. This non-linear accumulation of sub-harmonics over lower frequencies can boost classification systems accuracy.

It is understood that the above descriptions are for purposes of illustration and are not meant to be limiting.

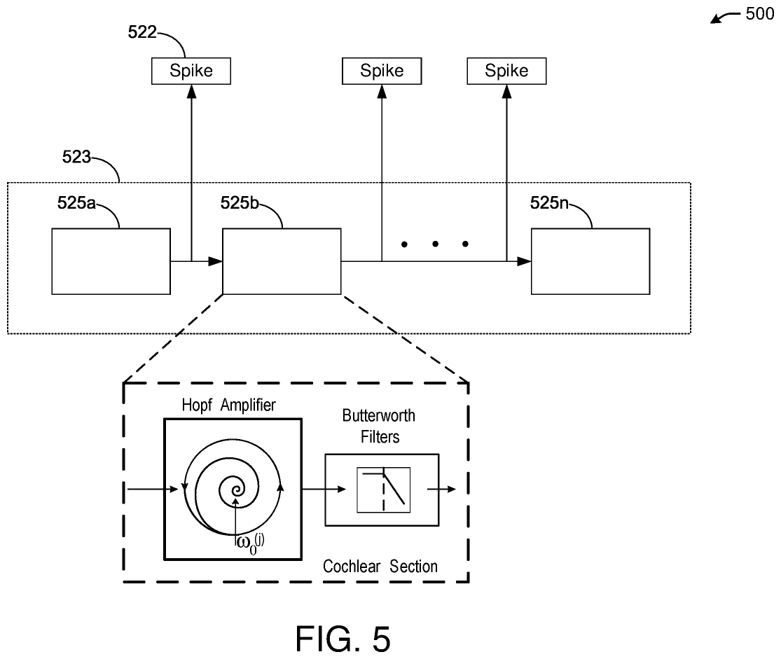

FIG. 5 depicts an illustrative schematic diagram for peak self-normalization, in accordance with one or more example embodiments of the present disclosure.

Referring to FIG. 5, there is shown a number of spikes that are introduced at the output of each Hopf resonator 525 (e.g., resonators 525a, 525b, . . . , 525n) of the filter bank 523.

In one or more embodiments, utilizing a dedicated asynchronous event-based processor (where the events are defined as spikes among the minimal computational blocks—the neurons), a peak self-normalization system may efficiently implement complex neuron dynamics integrating various differential equations including Hopf's. The peak self-normalization system, based on Hopf resonators (e.g., the Hopf resonators 525 in the filter bank 523), may be particularly convenient because of its simplicity, compactness, and the many emerging properties it highlights. When each Hopf resonator 525 is coupled to a spiking mechanism, the potential is even larger. This may be achieved by encoding a signal's spectrum in a sparse, event-driven manner with spikes, the communication bandwidth is automatically compressed without increasing latency. In testing, the required output was reduced by 47 times and still being able to reconstruct the original sound wave when compared to a conventional STFT which produces a spectrogram vector on each time step.

It is understood that the above descriptions are for purposes of illustration and are not meant to be limiting.

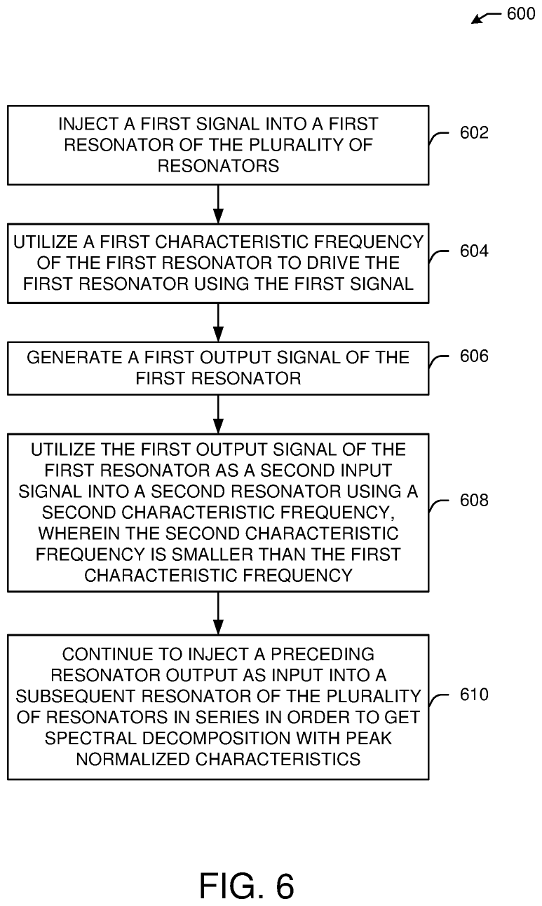

FIG. 6 illustrates a flow diagram of a process 600 for a peak self-normalization system, in accordance with one or more example embodiments of the present disclosure.

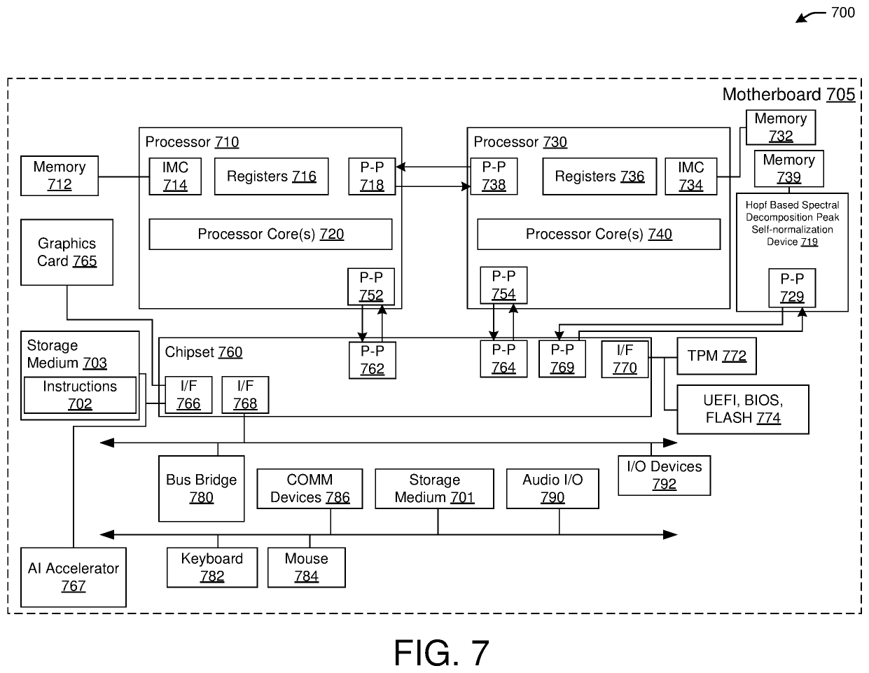

At block 602, a controller device (e.g., the peak self-normalization device of FIG. 1 and/or the peak self-normalization device 709 of FIG. 7) may inject a first signal into a first resonator of the plurality of resonators.

At block 604, the device may utilize a first characteristic frequency of the first resonator to drive the first resonator using the first signal.

At block 606, the device may generate a first output signal of the first resonator.

At block 608, the device may utilize the first output signal of the first resonator as a second input signal into a second resonator using a second characteristic frequency, wherein the second characteristic frequency is smaller than the first characteristic frequency.

At block 610, the device may continue to inject a preceding resonator output as input into a subsequent resonator of the plurality of resonators in series in order to get spectral decomposition with peak normalized characteristics.

In one or more embodiments, the relationship between the plurality of resonators cascaded in series is ω₀^{(j)}>ω₀^{(j+1)} moving from a high-frequency (HF) to a low-frequency (LF), where ω₀^{(j)} is a characteristic frequency of the j^{th} resonator in the filter bank, where j is a positive integer.

In one or more embodiments, each of the plurality of resonators in the filter bank comprise a Hopf amplifier coupled to a butterworth lowpass filter. The butterworth lowpass filter is a6^{th} order butterworth lowpass filter. The butterworth lowpass filter has a cutoff at 1.05ω₀. A first sensitivity factor may be used with driving the first resonator.

In one or more embodiments, the first resonator in the plurality of resonators cascaded in series amplifies or compresses weak or loud signals. An increased number of resonators increases the peak normalization becomes tighter.

It is understood that the above descriptions are for purposes of illustration and are not meant to be limiting.

FIG. 7 illustrates an embodiment of an exemplary system 700, in accordance with one or more example embodiments of the present disclosure.

In various embodiments, the computing system 700 may comprise or be implemented as part of an electronic device.

In some embodiments, the computing system 700 may be representative, for example, of computer system 120 of FIG. 1.

The embodiments are not limited in this context. More generally, the computing system 700 is configured to implement all logic, systems, processes, logic flows, methods, equations, apparatuses, and functionality described herein and with reference to FIGS. 1-6.

The system 700 may be a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, a handheld device such as a personal digital assistant (PDA), or other devices for processing, displaying, or transmitting information. Similar embodiments may comprise, e.g., entertainment devices such as a portable music player or a portable video player, a smart phone or other cellular phones, a telephone, a digital video camera, a digital still camera, an external storage device, or the like. Further embodiments implement larger scale server configurations. In other embodiments, the system 700 may have a single processor with one core or more than one processor. Note that the term “processor” refers to a processor with a single core or a processor package with multiple processor cores.

In at least one embodiment, the computing system 700 is representative of one or more components of FIG. 1. More generally, the computing system 700 is configured to implement all logic, systems, processes, logic flows, methods, apparatuses, and functionality described herein with reference to the above figures.

As used in this application, the terms “system” and “component” and “module” are intended to refer to a computer-related entity, either hardware, a combination of hardware and software, software, or software in execution, examples of which are provided by the exemplary system 700. For example, a component can be, but is not limited to being, a process running on a processor, a processor, a hard disk drive, multiple storage drives (of optical and/or magnetic storage medium), an object, an executable, a thread of execution, a program, and/or a computer.

By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

As shown in this figure, system 700 comprises a motherboard 705 for mounting platform components. The motherboard 705 is a point-to-point interconnect platform that includes a processor 710, a processor 730coupled via a point-to-point interconnects as an Ultra Path Interconnect (UPI), and a Hopf based spectral decomposition peak self-normalization device 719. In other embodiments, the system 700 may be of another bus architecture, such as a multi-drop bus. Furthermore, each of processors 710 and 730 may be processor packages with multiple processor cores. As an example, processors 710 and 730 are shown to include processor core(s) 720 and 740, respectively. While the system 700 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform refers to the motherboard with certain components mounted such as the processors 710 and the chipset 760. Some platforms may include additional components and some platforms may only include sockets to mount the processors and/or the chipset.

The processors 710 and 730 can be any of various commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures may also be employed as the processors 710, and 730.

The processor 710 includes an integrated memory controller (IMC) 714 and point-to-point (P-P) interfaces 718 and 752. Similarly, the processor 730 includes an IMC 734 and P-P interfaces 738 and 754. The IMC's 714 and 734 couple the processors 710 and 730, respectively, to respective memories, a memory 712 and a memory 732. The memories 712 and 732 may be portions of the main memory (e.g., a dynamic random-access memory (DRAM)) for the platform such as double data rate type 3 (DDR3) or type 4 (DDR4) synchronous DRAM (SDRAM). In the present embodiment, the memories 712 and 732 locally attach to the respective processors 710 and 730.

In addition to the processors 710 and 730, the system 700 may include a Hopf based spectral decomposition peak self-normalization device 719. The Hopf based spectral decomposition peak self-normalization device 719 may be connected to chipset 760 by means of P-P interfaces 729 and 769. The Hopf based spectral decomposition peak self-normalization device 719 may also be connected to a memory 739. In some embodiments, the Hopf based spectral decomposition peak self-normalization device 719 may be connected to at least one of the processors 710 and 730. In other embodiments, the memories 712, 732, and 739 may couple with the processor 710 and 730, and the Hopf based spectral decomposition peak self-normalization device 719 via a bus and shared memory hub.

System 700 includes chipset 760 coupled to processors 710 and 730. Furthermore, chipset 760 can be coupled to storage medium 703, for example, via an interface (I/F) 766. The I/F 766 may be, for example, a Peripheral Component Interconnect—enhanced (PCI-e). The processors 710, 730, and the peak self-normalization device 719 may access the storage medium 703 through chipset 760.

Storage medium 703 may comprise any non-transitory computer-readable storage medium or machine-readable storage medium, such as an optical, magnetic or semiconductor storage medium. In various embodiments, storage medium 703 may comprise an article of manufacture. In some embodiments, storage medium 703 may store computer-executable instructions, such as computer-executable instructions 702 to implement one or more of processes or operations described herein, (e.g., process 600 of FIG. 6). The storage medium 703 may store computer-executable instructions for any equations depicted above. The storage medium 703 may further store computer-executable instructions for models and/or networks described herein, such as a neural network or the like. Examples of a computer-readable storage medium or machine-readable storage medium may include any tangible media capable of storing electronic data, including volatile memory or non-volatile memory, removable or non-removable memory, erasable or non-erasable memory, writeable or re-writeable memory, and so forth. Examples of computer-executable instructions may include any suitable types of code, such as source code, compiled code, interpreted code, executable code, static code, dynamic code, object-oriented code, visual code, and the like. It should be understood that the embodiments are not limited in this context.

The processor 710 couples to a chipset 760 via P-P interfaces 752 and 762 and the processor 730 couples to a chipset 760 via P-P interfaces 754 and 764. Direct Media Interfaces (DMIs) may couple the P-P interfaces 752 and 762 and the P-P interfaces 754 and 764, respectively. The DMI may be a high-speed interconnect that facilitates, e.g., eight Giga Transfers per second (GT/s) such as DMI 3.0. In other embodiments, the processors 710 and 730 may interconnect via a bus.

The chipset 760 may comprise a controller hub such as a platform controller hub (PCH). The chipset 760 may include a system clock to perform clocking functions and include interfaces for an I/O bus such as a universal serial bus (USB), peripheral component interconnects (PCIs), serial peripheral interconnects (SPIs), integrated interconnects (I2Cs), and the like, to facilitate connection of peripheral devices on the platform. In other embodiments, the chipset 760 may comprise more than one controller hub such as a chipset with a memory controller hub, a graphics controller hub, and an input/output (I/O) controller hub.

In the present embodiment, the chipset 760 couples with a trusted platform module (TPM) 772 and the UEFI, BIOS, Flash component 774 via an interface (I/F) 770. The TPM 772 is a dedicated microcontroller designed to secure hardware by integrating cryptographic keys into devices. The UEFI, BIOS, Flash component 774 may provide pre-boot code.

Furthermore, chipset 760 includes the I/F 766 to couple chipset 760 with a high-performance graphics engine, graphics card 765. In other embodiments, the system 700 may include a flexible display interface (FDI) between the processors 710 and 730 and the chipset 760. The FDI interconnects a graphics processor core in a processor with the chipset 760.

Various I/O devices 792 couple to the bus 781, along with a bus bridge 780 which couples the bus 781 to a second bus 791 and an I/F 768 that connects the bus 781 with the chipset 760. In one embodiment, the second bus 791 may be a low pin count (LPC) bus. Various devices may couple to the second bus 791 including, for example, a keyboard 782, a mouse 784, communication devices 786, a storage medium 701, and an audio I/O 790.

The artificial intelligence (AI) accelerator 767 may be circuitry arranged to perform computations related to AI. The AI accelerator 767 may be connected to storage medium 703 and chipset 760. The AI accelerator 767 may deliver the processing power and energy efficiency needed to enable abundant-data computing. The AI accelerator 767 is a class of specialized hardware accelerators or computer systems designed to accelerate artificial intelligence and machine learning applications, including artificial neural networks and machine vision. The AI accelerator 767 may be applicable to algorithms for robotics, internet of things, other data-intensive and/or sensor-driven tasks.

Many of the I/O devices 792, communication devices 786, and the storage medium 701 may reside on the motherboard 705 while the keyboard 782 and the mouse 784 may be add-on peripherals. In other embodiments, some or all the I/O devices 792, communication devices 786, and the storage medium 701 are add-on peripherals and do not reside on the motherboard 705. Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions which, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chipset, memory, or the like. Integrated circuits include circuits created on a substrate such as a silicon wafer and may comprise components. And integrated circuits, processor packages, chip packages, and chipsets may comprise one or more processors.

Processors may receive signals such as instructions and/or data at the input(s) and process the signals to generate the at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, a smartphone, a tablet, a netbook, a wireless terminal, a laptop computer, a femtocell, a high data rate (HDR) subscriber station, an access point, a printer, a point of sale device, an access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as “communicating,” when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

The following examples pertain to further embodiments.

Example 1 may include a system that may comprise at least one memory that stores computer-executable instructions; a filter bank composed of a plurality of resonators cascaded in series, wherein a number of the plurality or resonators may be chosen to achieve a peak normalization; a controller to drive the filter bank, wherein the controller may be configured to access the at least one memory and execute the computer-executable instructions to: inject a first signal into a first resonator of the plurality of resonators; utilize a first characteristic frequency of the first resonator to drive the first resonator using the first signal; generate a first output signal of the first resonator; utilize the first output signal of the first resonator as a second input signal into a second resonator using a second characteristic frequency, wherein the second characteristic frequency may be smaller than the first characteristic frequency; and continue to inject a preceding resonator output as input into a subsequent resonator of the plurality of resonators in series in order to get spectral decomposition with peak normalized characteristics.

Example 2 may include the system of example 1 and/or some other example herein, wherein the relationship between the plurality of resonators cascaded in series may be ω₀^{(j)}>ω₀^{(j+1)} moving from a high-frequency (HF) to a low-frequency (LF), where ω₀^{(j)} may be a characteristic frequency of the jth resonator in the filter bank, where j may be a positive integer.

Example 3 may include the system of example 1 and/or some other example herein, wherein each of the plurality of resonators in the filter bank comprise a Hopf amplifier coupled to a butterworth lowpass filter.

Example 4 may include the system of example 3 and/or some other example herein, wherein the butterworth lowpass filter may be a 6th order butterworth lowpass filter.

Example 5 may include the system of example 3 and/or some other example herein, wherein the butterworth lowpass filter has a cutoff at 1.05ω₀.

Example 6 may include the system of example 1 and/or some other example herein, wherein a first sensitivity factor may be system with driving the first resonator.

Example 7 may include the system of example 1 and/or some other example herein, wherein the first resonator in the plurality of resonators cascaded in series amplifies or compresses weak or loud signals.

Example 8 may include the system of example 1 and/or some other example herein, wherein an increased number of resonators increases the peak normalization becomes tighter.

Example 9 may include a non-transitory computer-readable medium storing computer-executable instructions which when executed by one or more processors result in performing operations comprising: injecting a first signal into a first resonator of a plurality of resonators in a filter bank, wherein the plurality of resonators are cascaded in series, and wherein a number of the plurality or resonators may be chosen to achieve a peak normalization; utilizing a first characteristic frequency of the first resonator to drive the first resonator using the first signal; generating a first output signal of the first resonator; utilizing the first output signal of the first resonator as a second input signal into a second resonator using a second characteristic frequency, wherein the second characteristic frequency may be smaller than the first characteristic frequency; and continuing to inject a preceding resonator output as input into a subsequent resonator of the plurality of resonators in series in order to get spectral decomposition with peak normalized characteristics.

Example 10 may include the device of example 9 and/or some other example herein, wherein the relationship between the plurality of resonators cascaded in series may be ω₀^{(j)}>ω₀^{(j)} moving from a high-frequency (HF) to a low-frequency (LF), where ω₀^{(j)} may be a characteristic frequency of the jth resonator in the filter bank, where j may be a positive integer.

Example 11 may include the non-transitory computer-readable medium of example 9 and/or some other example herein, wherein each of the plurality of resonators in the filter bank comprise a Hopf amplifier coupled to a butterworth lowpass filter.

Example 12 may include the non-transitory computer-readable medium of example 11 and/or some other example herein, wherein the butterworth lowpass filter may be a 6th order butterworth lowpass filter.

Example 13 may include the non-transitory computer-readable medium of example 11 and/or some other example herein, wherein the butterworth lowpass filter has a cutoff at 1.05ω₀.

Example 14 may include the non-transitory computer-readable medium of example 9 and/or some other example herein, wherein a first sensitivity factor may be used with driving the first resonator.

Example 15 may include the non-transitory computer-readable medium of example 9 and/or some other example herein, wherein the first resonator in the plurality of resonators cascaded in series amplifies or compresses weak or loud signals.

Example 16 may include the non-transitory computer-readable medium of example 9 and/or some other example herein, wherein an increased number of resonators increases the peak normalization becomes tighter.

Example 17 may include a method comprising: injecting a first signal into a first resonator of a plurality of resonators in a filter bank, wherein the plurality of resonators are cascaded in series, and wherein a number of the plurality or resonators may be chosen to achieve a peak normalization; utilizing a first characteristic frequency of the first resonator to drive the first resonator using the first signal; generating a first output signal of the first resonator; utilizing the first output signal of the first resonator as a second input signal into a second resonator using a second characteristic frequency, wherein the second characteristic frequency may be smaller than the first characteristic frequency; and continuing to inject a preceding resonator output as input into a subsequent resonator of the plurality of resonators in series in order to get spectral decomposition with peak normalized characteristics.

Example 18 may include the device of example 17 and/or some other example herein, wherein the relationship between the plurality of resonators cascaded in series may be ω₀ ^{(j)}>ω₀^{(j+1)} moving from a high-frequency (HF) to a low-frequency (LF), where ω₀^{(j)} may be a characteristic frequency of the jth resonator in the filter bank, where j may be a positive integer.

Example 19 may include the method of example 17 and/or some other example herein, wherein each of the plurality of resonators in the filter bank comprise a Hopf amplifier coupled to a butterworth lowpass filter.

Example 20 may include the method of example 19 and/or some other example herein, wherein the butterworth lowpass filter may be a 6th order butterworth lowpass filter.

Example 21 may include the method of example 19 and/or some other example herein, wherein the butterworth lowpass filter has a cutoff at 1.05ω₀.

Example 22 may include the method of example 17 and/or some other example herein, wherein a first sensitivity factor may be used with driving the first resonator.

Example 23 may include the method of example 17 and/or some other example herein, wherein the first resonator in the plurality of resonators cascaded in series amplifies or compresses weak or loud signals.

Example 24 may include the method of example 17 and/or some other example herein, wherein an increased number of resonators increases the peak normalization becomes tighter.

Example 25 may include an apparatus comprising means for: injecting a first signal into a first resonator of a plurality of resonators in a filter bank, wherein the plurality of resonators are cascaded in series, and wherein a number of the plurality or resonators may be chosen to achieve a peak normalization; utilizing a first characteristic frequency of the first resonator to drive the first resonator using the first signal; generating a first output signal of the first resonator; utilizing the first output signal of the first resonator as a second input signal into a second resonator using a second characteristic frequency, wherein the second characteristic frequency may be smaller than the first characteristic frequency; and continuing to inject a preceding resonator output as input into a subsequent resonator of the plurality of resonators in series in order to get spectral decomposition with peak normalized characteristics.

Example 26 may include the device of example 25 and/or some other example herein, wherein the relationship between the plurality of resonators cascaded in series may be ω₀^{(j)}>ω₀^{(j+1)} moving from a high-frequency (HF) to a low-frequency (LF), where ω₀^{(j)} may be a characteristic frequency of the jth resonator in the filter bank, where j may be a positive integer.

Example 27 may include the apparatus of example 25 and/or some other example herein, wherein each of the plurality of resonators in the filter bank comprise a Hopf amplifier coupled to a butterworth lowpass filter.

Example 28 may include the apparatus of example 27 and/or some other example herein, wherein the butterworth lowpass filter may be a 6th order butterworth lowpass filter.

Example 29 may include the apparatus of example 27 and/or some other example herein, wherein the butterworth lowpass filter has a cutoff at 1.05ω₀.

Example 30 may include the apparatus of example 25 and/or some other example herein, wherein a first sensitivity factor may be used with driving the first resonator.

Example 31 may include the apparatus of example 25 and/or some other example herein, wherein the first resonator in the plurality of resonators cascaded in series amplifies or compresses weak or loud signals.

Example 32 may include the apparatus of example 25 and/or some other example herein, wherein an increased number of resonators increases the peak normalization becomes tighter.

Example 33 may include one or more non-transitory computer-readable media comprising instructions to cause an electronic device, upon execution of the instructions by one or more processors of the electronic device, to perform one or more elements of a method described in or related to any of examples 1-32, or any other method or process described herein.

Example 34 may include an apparatus comprising logic, modules, and/or circuitry to perform one or more elements of a method described in or related to any of examples 1-32, or any other method or process described herein.

Example 35 may include a method, technique, or process as described in or related to any of examples 1-32, or portions or parts thereof.

Example 36 may include an apparatus comprising: one or more processors and one or more computer readable media comprising instructions that, when executed by the one or more processors, cause the one or more processors to perform the method, techniques, or process as described in or related to any of examples 1-32, or portions thereof.

Example 37 may include a method of communicating in a wireless network as shown and described herein.

Example 38 may include a system for providing wireless communication as shown and described herein.

Example 39 may include a device for providing wireless communication as shown and described herein.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A system, comprising:
at least one memory that stores computer-executable instructions;
a filter bank composed of a plurality of resonators cascaded in series, wherein a number of the plurality or resonators is chosen to achieve a peak normalization;
a controller to drive the filter bank, wherein the controller is configured to access the at least one memory and execute the computer-executable instructions to:
inject a first signal into a first resonator of the plurality of resonators;
utilize a first characteristic frequency of the first resonator to drive the first resonator using the first signal;
generate a first output signal of the first resonator;
utilize the first output signal of the first resonator as a second input signal into a second resonator using a second characteristic frequency, wherein the second characteristic frequency is smaller than the first characteristic frequency; and
continue to inject a preceding resonator output as input into a subsequent resonator of the plurality of resonators in series in order to get spectral decomposition with peak normalized characteristics.

2. The system of claim 1, wherein the relationship between the plurality of resonators cascaded in series is ω_0^((j))>ω_0^((j+1)) moving from a high-frequency (HF) to a low-frequency (LF), where ω_0^((j)) is a characteristic frequency of the jth resonator in the filter bank, where j is a positive integer.

3. The system of claim 1, wherein each of the plurality of resonators in the filter bank comprise a Hopf amplifier coupled to a butterworth lowpass filter.

4. The system of claim 3, wherein the butterworth lowpass filter is a 6th order butterworth lowpass filter.

5. The system of claim 3, wherein the butterworth lowpass filter has a cutoff at 1.05ω_0.

6. The system of claim 1, wherein a first sensitivity factor is used with driving the first resonator.

7. The system of claim 1, wherein the first resonator in the plurality of resonators cascaded in series amplifies or compresses weak or loud signals.

8. The system of claim 1, wherein an increased number of resonators increases the peak normalization becomes tighter.

9. A non-transitory computer-readable medium storing computer-executable instructions which when executed by one or more processors result in performing operations comprising:
injecting a first signal into a first resonator of a plurality of resonators in a filter bank, wherein the plurality of resonators are cascaded in series, and wherein a number of the plurality or resonators is chosen to achieve a peak normalization;
utilizing a first characteristic frequency of the first resonator to drive the first resonator using the first signal;
generating a first output signal of the first resonator;
utilizing the first output signal of the first resonator as a second input signal into a second resonator using a second characteristic frequency, wherein the second characteristic frequency is smaller than the first characteristic frequency; and
continuing to inject a preceding resonator output as input into a subsequent resonator of the plurality of resonators in series in order to get spectral decomposition with peak normalized characteristics.

10. The device of claim 9, wherein the relationship between the plurality of resonators cascaded in series is ω_0^((j))>ω_0^((j+1)) moving from a high-frequency (HF) to a low-frequency (LF), where ω_0^((j)) is a characteristic frequency of the jth resonator in the filter bank, where j is a positive integer.

11. The non-transitory computer-readable medium of claim 9, wherein each of the plurality of resonators in the filter bank comprise a Hopf amplifier coupled to a butterworth lowpass filter.

12. The non-transitory computer-readable medium of claim 11, wherein the butterworth lowpass filter is a 6th order butterworth lowpass filter.

13. The non-transitory computer-readable medium of claim 11, wherein the butterworth lowpass filter has a cutoff at 1.05ω_0.

14. The non-transitory computer-readable medium of claim 9, wherein a first sensitivity factor is used with driving the first resonator.

15. The non-transitory computer-readable medium of claim 9, wherein the first resonator in the plurality of resonators cascaded in series amplifies or compresses weak or loud signals.

16. The non-transitory computer-readable medium of claim 9, wherein an increased number of resonators increases the peak normalization becomes tighter.

17. A method comprising:
injecting a first signal into a first resonator of a plurality of resonators in a filter bank, wherein the plurality of resonators are cascaded in series, and wherein a number of the plurality or resonators is chosen to achieve a peak normalization;
utilizing a first characteristic frequency of the first resonator to drive the first resonator using the first signal;
generating a first output signal of the first resonator;
utilizing the first output signal of the first resonator as a second input signal into a second resonator using a second characteristic frequency, wherein the second characteristic frequency is smaller than the first characteristic frequency; and
continuing to inject a preceding resonator output as input into a subsequent resonator of the plurality of resonators in series in order to get spectral decomposition with peak normalized characteristics.

18. The device of claim 17, wherein the relationship between the plurality of resonators cascaded in series is ω_0^((j))>w ω_0^((j+1)) moving from a high-frequency (HF) to a low-frequency (LF), where ω_0^((j)) is a characteristic frequency of the jth resonator in the filter bank, where j is a positive integer.

19. The method of claim 17, wherein each of the plurality of resonators in the filter bank comprise a Hopf amplifier coupled to a butterworth lowpass filter.

20. The method of claim 19, wherein the butterworth lowpass filter is a 6th order butterworth lowpass filter.
